(19) United States
(12) Patent Application Publication
(10) Pub. No.: US 2015/0249318 A1
(43) Pub. Date: Sep. 3, 2015

(54) NON-EVANESCENT HYBRID LASER

(71) Applicant: HEWLETT-PACKARD DEVELOPMENT COMPANY, LP, Houston, TX (US)

(72) Inventors: David A. Fattal, Mountain View, CA (US); Zhen Peng, Foster City, CA (US); Di Liang, Santa Barbara, CA (US)

(21) Appl. No.: 14/426,416

(22) PCT Filed: Sep. 27, 2012
(86) PCT No.: PCT/US2012/057673

§ 371 Date: Mar. 6, 2015

(51) Int. Cl. H01S 5/026; H01S 5/343; H01S 5/10; H01S 5/14

(52) U.S. Cl. CPC H01S 5/026; H01S 5/141; H01S 5/343; H01S 5/1032

(57) ABSTRACT

A non-evanescent hybrid laser. The laser includes an elongated waveguide including grating reflectors defining a laser cavity, a thin-film dielectric adjacent the laser cavity, and a group III-V wafer carried by the waveguide adjacent the laser cavity, separated from the laser cavity by the dielectric, and in non-evanescent optical communication with the laser cavity.

### BACKGROUND

Optical devices fabricated on CMOS-compatible platforms such as silicon have become more attractive as cost of fabrication has come down and more applications have been developed. Technology for fabricating silicon integrated circuits is readily adapted to making silicon photonic devices other than lasers. However, silicon has poor light-emitting qualities because it is an indirect bandgap semiconductor and for that reason has not been found to be suitable for making lasers. Hybrid lasers of silicon combined with group III-V semiconductor material have been developed to address this lack of silicon lasers. The hybrid approach takes advantage of the high gain light-emitting properties of group III-V materials and the process maturity of silicon. The group III-V material enhances the confinement factor and makes it possible to build electrically-driven lasers in a silicon wafer. Since these lasers are built in silicon, they can readily be integrated with other silicon photonic devices.

Wafer bonding techniques have been applied to make evanescent hybrid lasers by bonding group III-V material onto silicon waveguides. These lasers depend on evanescent coupling between the III-V material and the silicon (an “evanescent” optical signal is one that decays exponentially with distance after crossing a boundary despite hitting the boundary at an angle of total internal reflection). In this type of laser, the passive waveguide comprises a resonator structure, either a ring resonator or a Fabry-Perot cavity, formed by two grating reflectors acting as mirrors. The optical energy resides mostly in that passive region and overlaps only slightly with the I II-V gain material. If the interaction region between the optical mode and the gain medium is long enough, the device can lase.

### BRIEF DESCRIPTION OF THE DRAWINGS

The figures are not drawn to scale. They illustrate the disclosure by examples.

FIG. 1 is a side sectional view of an example of a non-evanescent hybrid laser.

FIG. 2 is a top view of another example of a non-evanescent hybrid laser.

FIG. 2A is a sectional view taken along the line A-A of FIG. 2.

FIG. 2B is a sectional view taken along the line B-B of FIG. 2.

FIG. 3 is a top view of an optical waveguide in another example of a non-evanescent hybrid laser.

FIG. 4 is a graph showing laser activity Q as a function of cavity length L in an example of a non-evanescent hybrid laser.

FIG. 5 is a top view of electrical contacts for a quantum well in another example of a non-evanescent hybrid laser.

### DETAILED DESCRIPTION

Illustrative examples and details are used in the drawings and in this description, but other configurations may exist and may suggest themselves. Parameters such as voltages, temperatures, dimensions, and component values are approximate. Terms of orientation such as up, down, top, and bottom are used only for convenience to indicate spatial relationships of components with respect to each other, and except as otherwise indicated, orientation with respect to external axes is not critical. For clarity, some known methods and structures have not been described in detail.

Hybrid silicon/group III-V lasers have many potential applications. However, evanescent hybrid lasers depend on compromises in design and fabrication between silicon waveguide confinement and quantum well confinement. Typically the optical mode overlaps only slightly with the gain region, which implies devices with long cavities operating at slower speeds. There remains a need for high-speed hybrid silicon or silicon nitride lasers having short laser cavities that use less power and provide more modulation bandwidth than existing hybrid evanescent lasers.

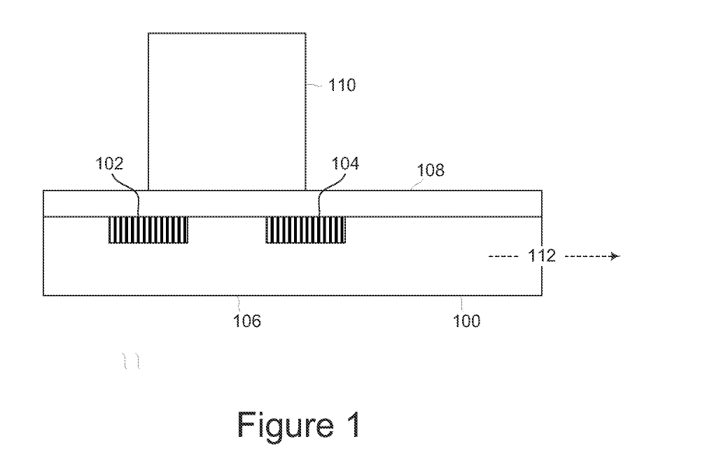

FIG. 1 gives an example of a non-evanescent hybrid laser. An elongated waveguide 100 includes grating reflectors 102 and 104 defining a laser cavity 106. A thin-film dielectric 108 is adjacent the laser cavity 106. A group III-V wafer 110 is carried by the waveguide 100 adjacent the laser cavity 106, separated from the laser cavity by the dielectric 108, and in non-evanescent optical communication with the laser cavity.

The optical mode extends (is “sucked up”) from the laser cavity 106 into the III-V wafer 110 to increase the overlap with the gain region, in contrast with traditional evanescent coupling, enabling the wafer 110 to provide gain for lasing in the waveguide. This represents natural-mode coupling through the dielectric 108, greatly enhancing the confinement factor as compared with evanescent coupling across a boundary between a silicon laser cavity and a III-V wafer. Optical energy exits the waveguide as indicated by an arrow 112.

In some examples the grating 102, distal from where the optical energy exits the waveguide, is characterized by an optical resistance R that is greater than that of the grating 104 that is proximal to the optical energy exit.

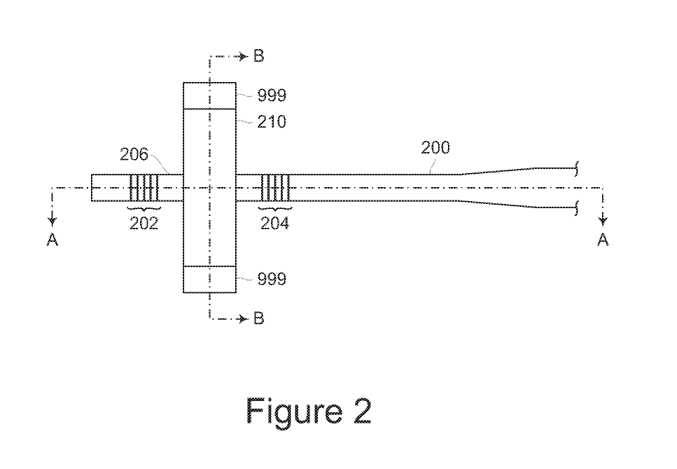

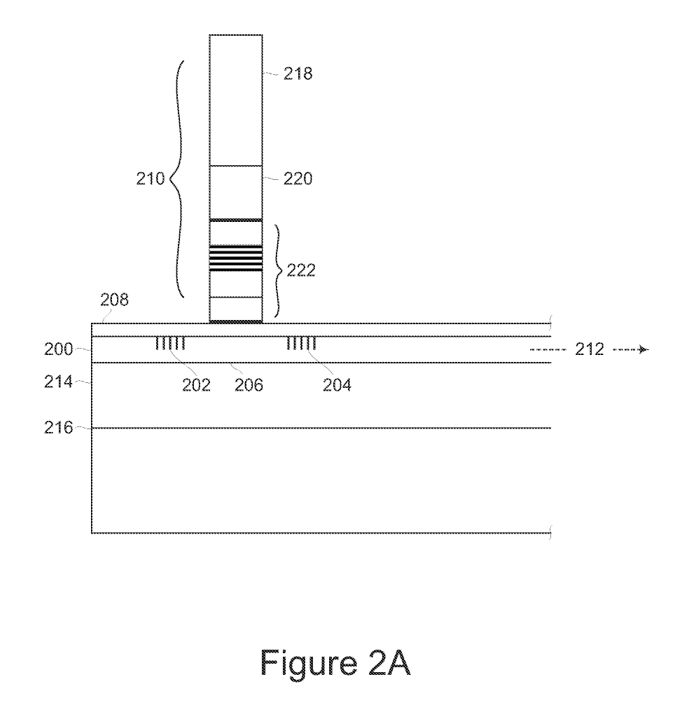

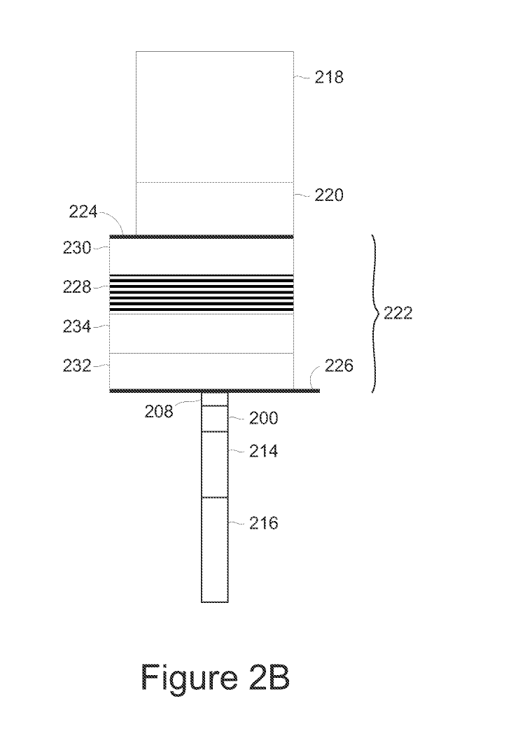

FIGS. 2, 2A and 2B give another example of a non-evanescent hybrid laser. An elongated waveguide 200 includes grating reflectors 202 and 204 defining a laser cavity 206. In some examples the waveguide comprises a silicon nitride, for example Si₃N₄. In other examples oxides or other compounds of silicon such as silicon carbide, silicon-germanium, or an SOI material system, or germanium alone, may be used. A thin-film dielectric 208 (not shown in FIG. 2 for clarity) covers the laser cavity 206, In some examples the dielectric 208 comprises an oxide of silicon. A group III-V epitaxial wafer 210 is bonded to the waveguide 200 adjacent the laser cavity 206 and separated from the laser cavity by the dielectric 208. The wafer 210, which provides gain for lasing, is in non-evanescent optical communication with the laser cavity 206, the optical mode extending through both the wafer 210 and the cavity 206. Optical energy exits the waveguide as indicated by an arrow 212.

In some examples the waveguide 200 rests on a buffer oxide layer 214 which in turn is carried by a substrate 216. The group III-V wafer 210 may comprise a substrate 218, a buffer layer 220 on the substrate 218, and a quantum well 222 on the buffer layer 220. In some examples the quantum well is fabricated in a vertical PIN structure for charge injection. In some examples the quantum well 222 includes first and second contact layers 224 and 226 and a plurality of active layers 228 between the contact layers. A wide bandgap layer 230 lies between the active layer 228 and the first contact layer 224. A substrate 232 lies on the second contact layer 226, and a wide bandgap layer 234 lies between the substrate 234 and the active layers 228.

The group III-V wafer may comprise an epitaxial wafer grown by a process such as metal-organic chemical vapor deposition (MOCVD) or molecular-beam epitaxy (MBE). It may be fabricated of materials such as gallium nitride (GaN) or one or more of gallium, indium, phosphorus, nitrogen, arsenic, or aluminum.

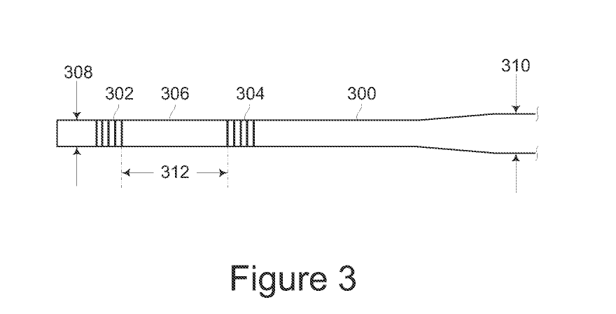

FIG. 3 illustrates an optical waveguide in another example of a non-evanescent hybrid laser. The waveguide 300 includes gratings 302 and 304 defining a laser cavity 306. In this example the waveguide is tapered from a minimum width 308 of about 1 to 4 micrometers (μm) to a maximum width 310 of about 2 to 10 μm. In other examples the waveguide is not tapered.

The length 312 of the laser cavity 306 is set to contain a full set of oscillations between the silicon nitride waveguide 300 and an overlying group III-V wafer (not shown in FIG. 3). If the cavity 306 does not do this, the optical energy may leak through the III-V wafer. When the length is set in this way, there is a node in the III-V wafer above the gratings. The quantum well could terminate at or above this node without incurring much scattering loss.

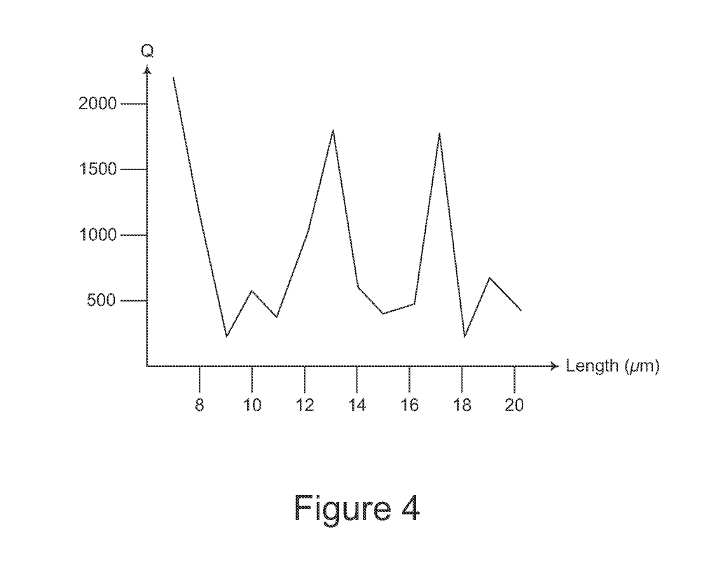

FIG. 4 shows the effect of cavity length L on laser activity Q in the foregoing hybrid laser example. Laser activity is low at cavity lengths above seven μm but there are peaks at lengths of 13 and 17 μm.

In an example (all values are approximate):
length of laser cavity L=13 μm,
wavelength λ=633 nm,
Q=6,000,
for the substrate, n=1.44,
for the dielectric film, n=1.44 and thickness=100 nm,
for the active layers of the quantum well, n=3.1 and thickness=150 nm,
for the waveguide, n=2.05 and thickness=260 nm, and
the gratings have lengths of about 5 μm.

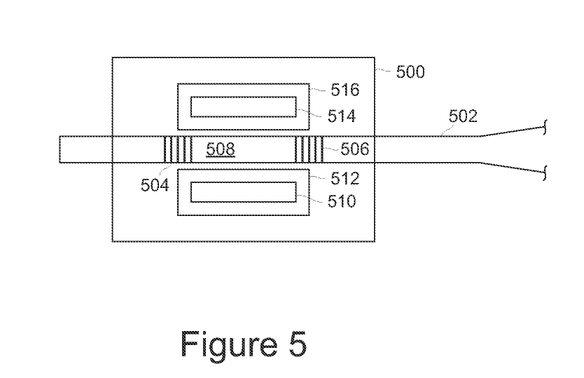

FIG. 5 gives an example of electrical contacts for a quantum well in a non-evanescent hybrid laser. A group III-V wafer 500 covers a silicon nitride waveguide 502. The waver extends over gratings 504 and 506 in the waveguide and a laser cavity 508 defined between the gratings. An electrical conductor 510 extends through a via 512 to a contact layer similar to the contact layer 224 of FIG. 2. Another electrical conductor 514 extends through a via 516 to a contact layer similar to the contact layer 226 of FIG. 2. The configuration of electrical contacts is not critical, and other arrangements will suggest themselves.

In the example of FIG. 1 the III-V wafer 110 extends over the entire length of the laser cavity 106 and partially covers the gratings 102 and 104. In the example of FIG. 2 the III-V waver 210 only covers a portion of the laser cavity 206 and does not cover any part of the gratings 202 and 204, and in the example of FIG. 5 the III-V wafer 500 extends far enough along the waveguide 502 to completely cover the laser cavity 508 and the gratings 504 and 506.

A non-evanescent hybrid laser offers a small footprint, fast and efficient optical device that operates at low power levels and can be fabricated on any CMOS-compatible waveguide platform (e.g. high index silicon, or lower index silicon nitride). This laser finds applications in a variety of optical interconnects, directional backlights, and in other applications where a small, low-power laser is needed.

What is claimed is:

1. A non-evanescent hybrid laser comprising:
an elongated waveguide including grating reflectors defining a laser cavity;
a thin-film dielectric adjacent the laser cavity; and
a group III-V wafer carried by the waveguide adjacent the laser cavity, separated from the laser cavity by the dielectric, and in non-evanescent optical communication with the laser cavity.

2. The laser of claim 1 wherein the waveguide comprises silicon nitride.

3. The laser of claim 2 wherein the waveguide comprises a substrate and a buffer oxide on the substrate, the silicon nitride being disposed on the buffer oxide.

4. The laser of claim 1 wherein the group III-V wafer comprises a substrate, a buffer on the substrate, and a quantum well on the buffer.

5. The laser of claim 4 wherein the quantum well comprises first and second contact layers and a plurality of active layers between the contact layers.

6. The laser of claim 5 wherein the quantum well comprises a PIN structure.

7. The laser of claim 1 wherein the group III-V wafer is bonded to the waveguide.

8. A non-evanescent hybrid laser comprising:
a waveguide;
a plurality of grating reflectors formed in the waveguide and defining a passive region;
a group III-V wafer defining an active region and carried by the waveguide adjacent the passive region; and
a thin-film dielectric between the passive and active regions, the active and passive regions in non-evanescent optical communication through the dielectric to define a laser.

9. The laser of claim 8 wherein the waveguide comprises silicon nitride.

10. The laser of claim 9 wherein the waveguide comprises a substrate and a buffer oxide on the substrate, the silicon nitride being disposed on the buffer oxide.

11. The laser of claim 8 wherein the group III-V wafer comprises a substrate, a buffer on the substrate, and a quantum well on the buffer.

12. The laser of claim 11 wherein the quantum well comprises first and second contact layers and a plurality of active layers between the contact layers.

13. The laser of claim 12 wherein the quantum well comprises a PIN structure.

14. The laser of claim 8 wherein the group III-V wafer is bonded to the waveguide.
